(19) United States
(12) Patent Application Publication
(10) Pub. No.: US 2026/0107800 A1
(43) Pub. Date: Apr. 16, 2026

(54) SEMICONDUCTOR PACKAGE WITH INTEGRATED GROUND LINES AND SIGNAL LINES

(71) Applicant: Samsung Electronics Co., Ltd., Suwon-si (KR)

(72) Inventors: Minjong WANG, Suwon-si (KR); Keunyoung LEE, Suwon-si (KR); Eunhye LEE, Suwon-si (KR)

(73) Assignee: Samsung Electronics Co., Ltd., Suwon-si (KR)

(21) Appl. No.: 19/089,703

(22) Filed: Mar. 25, 2025

(30) Foreign Application Priority Data
Oct. 14, 2024 (KR) 10-2024-0139809

(51) Int. Cl. H01L 23/538; H01L 23/00; H01L 23/498; H01L 25/065; H01L 25/18; H10B 80/00; H10D 80/30

(52) U.S. Cl. CPC H10W 70/65; H10B 80/00; H10D 80/30; H10W 70/611; H10W 90/00; H10W 72/5522; H10W 72/5524; H10W 72/5525; H10W 90/24; H10W 90/701; H10W 90/732; H10W 90/734; H10W 90/752; H10W 90/754

(57) ABSTRACT

A semiconductor package includes: a package substrate including a first surface and a second surface opposite each other; at least one signal pad arranged in a first direction, at least one ground pad spaced apart from the at least one signal pad in a second direction; and a semiconductor chip on the package substrate, the semiconductor chip including at least one first pad and at least one second pad. The package substrate includes at least one signal line connected to the at least one signal pad; and a at least one ground line connected to the at least one ground pad, in which the at least one ground line extends between the at least one signal pad and the at least one ground pad in the first direction, and in which the at least one second pad is connected to the at least one ground pad through a second bonding wire.

### CROSS-REFERENCE TO RELATED APPLICATIONS

This U.S. non-provisional patent application claims priority under 35 U.S.C. § 119 to Korean Patent Application No.10-2024-0139809 filed on Oct. 14, 2024, in the Korean Intellectual Property Office, the entire contents of which are hereby incorporated by reference.

### BACKGROUND

The present disclosure relates to a semiconductor package, and more specifically, relates to a stacked semiconductor package in which a plurality of semiconductor chips are stacked on a substrate.

With the development of the electronics industry and the demands of users, electronic devices have become smaller and increasingly multifunctional. Accordingly, a need for smaller and more multifunctional semiconductor devices used in electronic devices has also increased, resulting in research to reduce the size of semiconductor packages and to improve the operating performance of semiconductor packages. Conventionally, vias were added between patterns for ground. However, a region where a pattern is formed increases, and a gap between bonding fingers is not sufficient. As a result, it is difficult to implement shielding that surrounds the fingers. Since shielding is difficult to implement, a cross talk phenomenon occurs.

### SUMMARY

An object of the present disclosure is to provide a semiconductor package with improved reliability.

According to an aspect of the disclosure, a semiconductor package includes a package substrate including a first surface and a second surface opposite to each other; at least one signal pad on the first surface of the package substrate, the first direction being a direction parallel to the first surface of the package substrate; at least one ground pad on the first surface of the package substrate and spaced apart from the signal pad in a second direction, the second direction being a direction parallel to the first surface of the package substrate and intersecting the first direction; and a semiconductor chip on the package substrate, the semiconductor chip comprising at least one first pad and at least one second pad, in which the package substrate further includes: at least one signal line connected to the at least one signal pad; and at least one ground line connected to the at least one ground pad, in which the at least one ground line extends between the at least one signal pad and the at least one ground pad in the first direction, in which the at least one first pad is connected to the at least one signal pad through a first bonding wire, and in which the at least one second pad is connected to the at least one ground pad through a second bonding wire.

According to an aspect of the disclosure, a semiconductor package includes: a package substrate including a first surface and a second surface opposite to each other; a first semiconductor chip on the first surface of the package substrate; a plurality of memory chips on the first surface of the package substrate; a plurality of first signal pads on the first surface of the package substrate and arranged in a first direction, the first direction being a direction parallel to the first surface of the package substrate; a plurality of ground pads on the first surface of the package substrate and arranged in the first direction and spaced apart from the plurality of first signal pads in a second direction, respectively, the second direction being a direction parallel to the first surface of the package substrate and intersecting the first direction; a plurality of second signal pads on the first surface of the package substrate and arranged in the first direction; a plurality of first bonding wires connecting the plurality of first signal pads and the first semiconductor chip, respectively; a plurality of second bonding wires connecting the plurality of ground pads and the first semiconductor chip, respectively; and a plurality of third bonding wires connecting the plurality of second signal pads and the plurality of memory chips, respectively, in which the plurality of first signal pads are disposed between the plurality of ground pads and the plurality of second signal pads, respectively, in which the package substrate includes: a plurality of signal lines connecting the plurality of first signal pads and the plurality of second signal pads, respectively; and a plurality of ground lines connected to the plurality of ground pads, respectively, and in which at least one of the plurality of ground lines extends between the plurality of ground pads and the plurality of first signal pads in the first direction, respectively.

According to an aspect of the disclosure, a semiconductor package includes: a package substrate including a first surface and a second surface opposite each other; a first semiconductor chip on the first surface of the package substrate; a plurality of memory chips on the first surface of the package substrate and stacked on the first semiconductor chip; a plurality of first signal pads arranged in a first direction on the first surface of the package substrate, the first direction being a direction parallel to the first surface of the package substrate; a plurality of ground pads arranged in the first direction on the first surface of the package substrate and spaced apart from the plurality of first signal pads, respectively, in a second direction, the second direction being a direction parallel to the first surface of the package substrate and intersecting the first direction; a plurality of second signal pads on the first surface of the package substrate and arranged in the first direction; a plurality of first bonding wires connecting the plurality of first signal pads and the first semiconductor chip, respectively; a plurality of second bonding wires connecting the plurality of ground pads and the first semiconductor chip, respectively; and a plurality of third bonding wires connecting the plurality of second signal pads and the plurality of memory chips, respectively, in which the plurality of first signal pads are between the plurality of ground pads and the plurality of second signal pads, respectively, in which the package substrate includes: a plurality of signal lines connecting the plurality of first signal pads and the plurality of second signal pads, respectively; and a plurality of ground lines connected to the plurality of ground pads, respectively, and in which at least one of the plurality of ground lines extends between the plurality of ground pads and the plurality of first signal pads in the first direction, respectively.

### BRIEF DESCRIPTION OF DRAWINGS

Example embodiments will be more clearly understood from the following brief description taken in conjunction with the accompanying drawings. The accompanying drawings represent non-limiting, example embodiments as described herein.

FIG. 1 is a plan view of a semiconductor package according to embodiments of the present disclosure.

FIG. 2 is a plan view taken along line A-A′ of FIG. 1 according to embodiments of the present disclosure.

FIG. 3 is a cross-sectional view of a semiconductor package according to other embodiments of the present disclosure.

FIG. 4 is a plan view of region ‘R1’ of FIG. 3 according to embodiments of the present disclosure.

FIG. 5 is a plan view of region ‘R2’ of FIG. 3.

FIG. 6 is a cross-sectional view of a semiconductor package according to other embodiments of the present disclosure.

FIG. 7 is a plan view of region ‘R3’ of FIG. 6 according to embodiments of the present disclosure.

FIG. 8 is a plan view of region ‘R4’ region of FIG. 6 according to embodiments of the present disclosure.

FIGS. 9A to 11A are plan views illustrating a method for manufacturing a semiconductor package according to embodiments of the present disclosure. FIGS. 9B to 11B are cross-sectional views along A-A′ of FIGS. 9A to 11A according to embodiments of the present disclosure.

### DETAILED DESCRIPTION

Hereinafter, the present disclosure will be described in detail by describing embodiments of the present disclosure with reference to the attached drawings.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

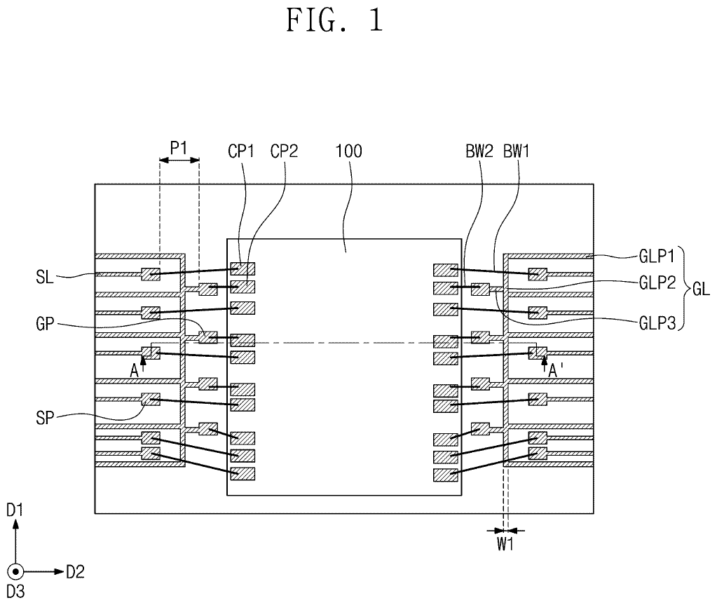

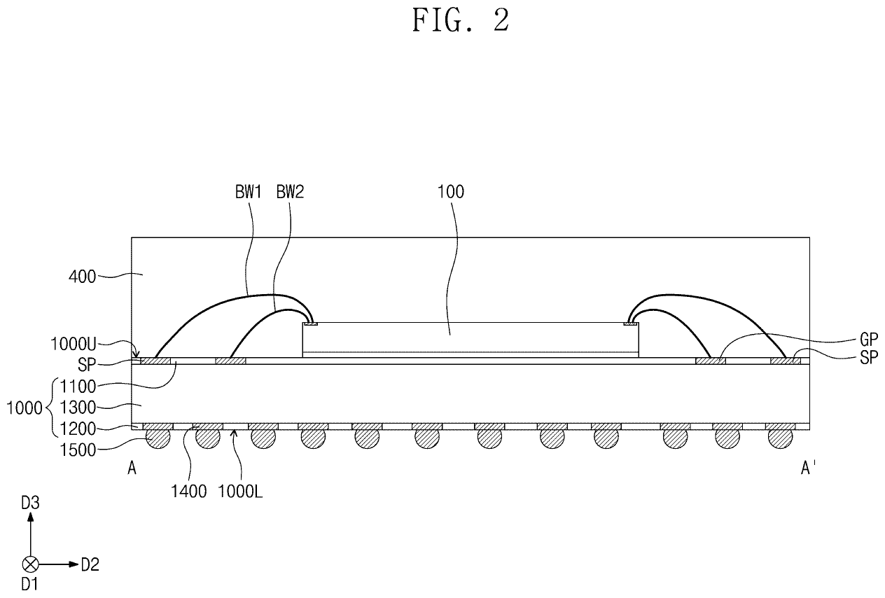

FIG. 1 is a plan view of a semiconductor package according to embodiments of the present disclosure. FIG. 2 is a plan view along line A-A′ of FIG. 1.

Referring to FIGS. 1 and 2, a package substrate 1000 including an upper surface 1000U and a lower surface 1000L facing each other may be provided. The package substrate 1000 may be, for example, a printed circuit board (PCB).

The package substrate 1000 may include a base layer 1300, an upper insulating layer 1100 on the base layer 1300, and a lower insulating layer 1200 below the base layer 1300. The base layer 1300 may include, for example, at least one material selected from the group consisting of a phenol resin, an epoxy resin, and a polyimide. The base layer may be formed of a single material. The base layer may be a composite formed of more than one material. The upper insulating layer 1100 and the lower insulating layer 1200 may include, for example, a photosensitive material. The photosensitive material may include, for example, a photo-imageable coverlay (PIC) and a photosensitive solder resist. In one or more examples, a PIC may be a material used to create flexible printed circuit boards. In one or more examples, a photosensitive solder resist may be a specialized type of solder resist material used in the semiconductor manufacturing process, which is sensitive to light and can be precisely patterned using photolithography to protect and insulate the intricate wiring on semiconductor packages, allowing for high-density circuit design with minimal solder bridges. The photosensitive solder resist may be a light-reactive coating that can be selectively removed to expose desired solder pads on the semiconductor substrate.

External connection pads 1400 may be disposed on the lower surface 1000L of the package substrate 1000. The lower insulating layer 1200 may expose lower surfaces of the external connection pads 1400. In one or more examples, the connection pads 1400 may include a conductive surface that connects a chip to a circuit board.

External connection terminals 1500 may be disposed on the lower surface 1000L of the package substrate 1000. The external connection terminals 1500 may be disposed on the external connection pads 1400, respectively, and may be electrically connected to the external connection pads 1400. The external connection terminals 1500 may be electrically connected to a plurality of signal pads and a plurality of ground pads, which will be described later, through internal wiring lines in the package substrate 1000. The external connection terminals 1500 may be, for example, solder balls or solder bumps.

A plurality of signal pads SP may be disposed on the upper surface 1000U of the package substrate 1000. The plurality of signal pads SP may be arranged in a first direction D1. The first direction D1 may be a direction parallel to the upper surface 1000U of the package substrate 1000. Each of the plurality of signal pads SP may include a conductive material. Each of the plurality of signal pads SP may include, for example, copper (Cu).

A plurality of ground pads GP may be disposed on the upper surface 1000U of the package substrate 1000. The plurality of ground pads GP may be arranged in the first direction D1. The plurality of ground pads GP may be spaced apart from the plurality of signal pads SP in a second direction D2. The plurality of ground pads GP may be spaced apart from the plurality of signal pads SP by a first pitch P1 in the second direction D2. In one or more examples, a pitch may be a distance between the centers of adjacent lines or interconnects. The second direction D2 may be parallel to the upper surface 1000U of the package substrate 1000 and may be a direction intersecting the first direction D1. Each of the plurality of ground pads GP may include a conductive material. Each of the plurality of ground pads GP may include, for example, copper (Cu). The upper insulating layer 1100 may expose upper surfaces of each of the plurality of signal pads SP and the plurality of ground pads GP.

The package substrate 1000 may include a plurality of signal lines SL electrically connected to the plurality of signal pads SP. The plurality of signal lines SL may be spaced apart from each other in the first direction D1 and may be respectively connected to the plurality of signal pads SP. The plurality of signal lines SL may extend in the second direction D2.

The package substrate 1000 may include a plurality of ground lines GL electrically connected to the plurality of ground pads GP.

At least one of the plurality of ground lines GL may extend between the plurality of signal pads SP and the plurality of ground pads GP in the first direction D1. At least one of the plurality of ground lines GL may extend between the plurality of signal lines SL in the second direction D2.

The plurality of ground lines GL may include first ground line patterns GLP1, second ground line patterns GLP2, and third ground line patterns GLP3. Each of the first ground line patterns GLP1 may extend in the second direction D2. The first ground line patterns GLP1 may be spaced apart from each other in the first direction D1 with at least one signal line among the plurality of signal lines SL interposed therebetween.

The second ground line pattern GLP2 may extend between the plurality of signal pads SP and the plurality of ground pads GP in the first direction D1. The second ground line pattern GLP2 may be electrically connected to the first ground line patterns GLP1.

The third ground line patterns GLP3 may extend from the second ground line pattern GLP2 in the second direction D2. The third ground line patterns GLP3 may be spaced apart from each other in the first direction D1. Each of the third ground line patterns GLP3 may be electrically connected to a corresponding ground pad among a plurality of first ground pads GP1. The upper insulating layer 1100 may cover the plurality of signal lines SL and the plurality of ground lines GL.

The second ground line pattern GLP2 may have a first width W1 in the second direction D2. The first pitch P1 may be greater than the first width W1. The first pitch P1 may be greater than 1 time of the first width W1 and may be less than or equal to 10 times the first width W1. The first width W1 may be 10 μm to 20 μm. The first pitch P1 may be greater than 10 μm and may be less than or equal to 200 μm.

When the first pitch P1 is smaller than the first width W1, at least one ground line cannot extend in the first direction D1 between the plurality of ground pads GP and the plurality of signal pads SP. That is, the plurality of signal lines SL may not be effectively ground shielded through the plurality of ground lines GL.

When the first pitch P1 is greater than 10 times the first width W1, a region where the plurality of signal lines SL and the plurality of ground lines GL are arranged may be excessively widened, thereby reducing integration.

In the semiconductor package according to the embodiments of the present disclosure, at least one of the plurality of ground lines GL (e.g., the second ground line pattern GLP2) may extend between the plurality of signal pads SP and the ground pads GP. At least one of the plurality of ground lines GL (e.g., the first ground line pattern GLP1) may extend between the plurality of signal lines SL. As a result, the plurality of signal lines SL may be ground shielded by the plurality of ground lines GL. As a result, interference or crosstalk between the plurality of signal lines SL may be advantageously prevented. Accordingly, a semiconductor package with improved reliability may be provided.

A semiconductor chip 100 may be disposed on the package substrate 1000. The semiconductor chip 100 may be spaced apart from the plurality of signal pads SP and the plurality of ground pads GP when viewed in a plan view. The semiconductor chip 100 may be spaced apart from the plurality of signal lines SL and the plurality of ground lines GL in the direction D2 when viewed in a plan view. The semiconductor chip 100 may include, for example, a memory semiconductor chip. For example, the semiconductor chip 100 may be a volatile memory semiconductor chip such as a dynamic random access memory (DRAM) or a static random access memory (SRAM). For example, the semiconductor chip 100 may be a nonvolatile memory semiconductor chip such as a phase-change random access memory (PRAM), a magnetic random access memory (MRAM), a ferroelectric random access memory (FeRAM), a resistive random access memory (RRAM), or any other memory structure known to one of ordinary skill in the art.

The semiconductor chip 100 may include, for example, a logic semiconductor chip. For example, the semiconductor chip 100 may include a logic semiconductor chip such as a central processor unit (CPU), a micro processor unit (MPU), a graphics processor unit (GPU), an application processor (AP), or any other processor structure known to one of ordinary skill in the art.

The semiconductor chip 100 may include a plurality of first pads CP1 and a plurality of second pads CP2. The plurality of first pads CP1 may be electrically connected to the plurality of signal pads SP through a plurality of first bonding wires BW1. For example, one end of each of the plurality of first bonding wires BW1 may be in contact with a corresponding signal pad among the plurality of signal pads SP. For example, the other end of each of the plurality of first bonding wires BW1 may be in contact with a corresponding first pad among the plurality of first pads CP1. The semiconductor chip 100 may transmit and/or provide a command signal, an address signal, and/or a data signal through the plurality of first pads CP1 and the plurality of signal pads SP.

The plurality of second pads CP2 may be electrically connected through the plurality of ground pads GP through a plurality of second bonding wires BW2. For example, one end of each of the plurality of second bonding wires BW2 may be in contact with a corresponding ground pad among the plurality of ground pads GP. For example, the other end of each of the plurality of second bonding wires BW2 may be in contact with a corresponding second pad among the plurality of second pads CP2. The semiconductor chip 100 may be grounded through the plurality of second pads CP2 and the plurality of ground pads GP.

Each of the plurality of first bonding wires BW1 and the plurality of second bonding wires BW2 may be formed of a material of at least one selected from the group consisting of copper, gold, aluminum, and alloys thereof.

A molding layer 400 may be disposed on the upper surface 1000U of the package substrate 1000. The molding layer 400 may cover the semiconductor chip 100. The molding layer 400 may include, for example, an epoxy molding compound.

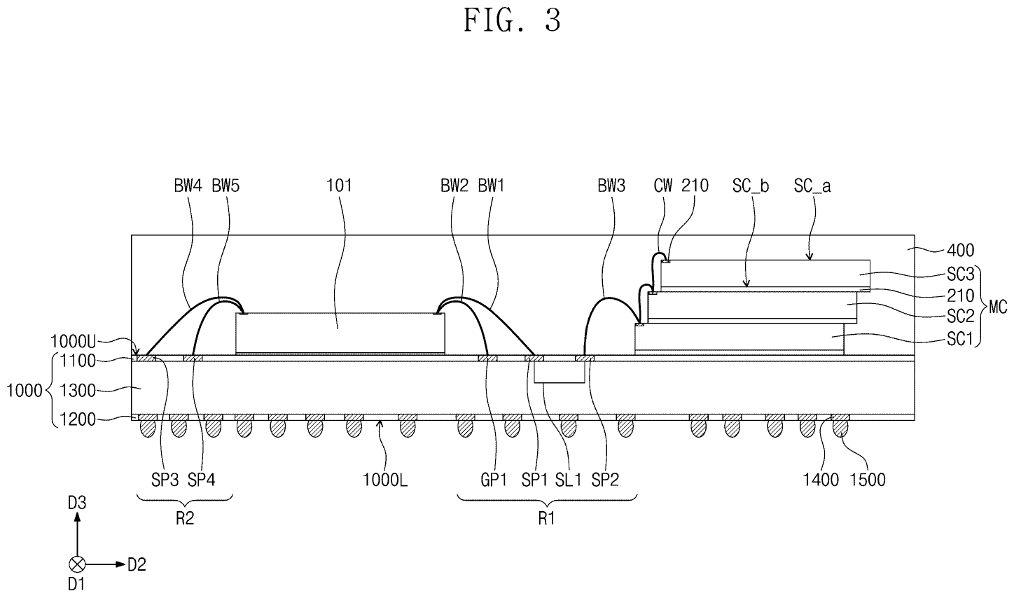

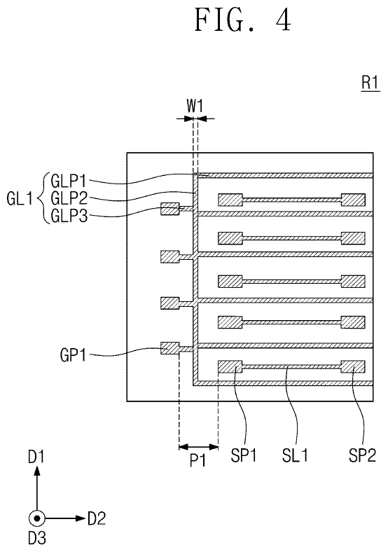

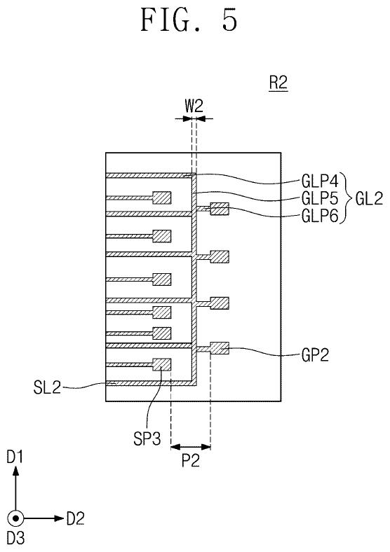

FIG. 3 is a cross-sectional view of a semiconductor package according to other embodiments of the present disclosure. FIG. 4 is a plan view of region ‘R1’ of FIG. 3. FIG. 5 is a plan view of region ‘R2’ of FIG. 3. For simplicity of explanation, descriptions overlapping those of the semiconductor package described with reference to FIGS. 1 and 2 are omitted.

Referring to FIG. 3, a package substrate 1000 including an upper surface 1000U and a lower surface 1000L facing each other may be provided. The package substrate 1000 may include a base layer 1300, an upper insulating layer 1100 on the base layer 1300, and a lower insulating layer 1200 below the base layer 1300. The upper insulating layer 1100 and the lower insulating layer 1200 may include, for example, a photosensitive material.

A first semiconductor chip 101 may be disposed on the upper surface 1000U of the package substrate 1000. The first semiconductor chip 101 may be, for example, a logic chip. The first semiconductor chip 101 may include, for example, a logic semiconductor chip such as a central processor unit (CPU), a micro processor unit (MPU), a graphics processor unit (GPU), or an application processor (AP).

A plurality of memory chips MC may be disposed on the upper surface 1000U of the package substrate 1000. The plurality of memory chips MC may be spaced apart from the first semiconductor chip 101 in a second direction D2 to form a stepped structure. In one or more examples, each of the memory chips may be spaced apart in the second direction by an equal amount. In one or more examples, at least one of the memory chips may be spaced apart by a different amount than the other memory chips.

The above-described plurality of memory chips MC may include a first semiconductor die SC1, a second semiconductor die SC2, and a third semiconductor die SC3. The first semiconductor die SC1 may be a semiconductor die adjacent to the package substrate 1000. The second semiconductor die SC2 may be a semiconductor die interposed between the first semiconductor die SC1 and the third semiconductor die SC3. Although three semiconductor dies are illustrated in FIG. 3, the semiconductor package according to embodiments of the present disclosure may have more or fewer semiconductor dies, and is not limited to the number of semiconductor dies illustrated in FIG. 3.

The first semiconductor die SC1 may be, for example, a logic chip. The first semiconductor die SC1 may include, for example, a logic semiconductor chip such as a central processor unit (CPU), a micro processor unit (MPU), a graphics processor unit (GPU), or an application processor (AP). The present disclosure is not limited thereto, and the first semiconductor die SC1 may be, for example, a memory semiconductor chip. The first semiconductor chip 101 may be, for example, a volatile memory semiconductor chip such as a dynamic random access memory (DRAM) or a static random access memory (SRAM). The first semiconductor die SC1 may be, for example, a nonvolatile memory semiconductor chip such as a flash memory, a phase-change random access memory (PRAM), a magnetic random access memory (MRAM), a ferroelectric random access memory (FeRAM), or a resistive random access memory (RRAM).

Each of the second semiconductor die SC2 and the third semiconductor die SC3 may be, for example, a volatile memory semiconductor chip such as a dynamic random access memory (DRAM) or a static random access memory (SRAM). Each of the second semiconductor die SC2 and the third semiconductor die SC3 may be a nonvolatile memory semiconductor chip, such as, for example, a flash memory, a phase-change random access memory (PRAM), a magnetic random access memory (MRAM), a ferroelectric random access memory (FeRAM), or a resistive random access memory (RRAM).

Each of the semiconductor dies SC1, SC2, and SC3 may include an upper surface SC_a and a lower surface SC_b facing each other. The lower surface SC_b may be a surface facing the package substrate 1000. The upper surface SC_a of each of the semiconductor dies SC1, SC2, and SC3 may be an active surface. Each of the semiconductor dies SC1, SC2, and SC3 may have a contact pad 210 disposed on the upper surface SC_a.

The contact pad 210 may include a connection terminal electrically connected to each of the semiconductor dies SC1, SC2, and SC3. The semiconductor dies SC1, SC2, and SC3 may be electrically connected to each other through a connection wire CW. The connection wire CW may be electrically connected to the contact pads 210 to electrically connect the semiconductor dies to each other.

A die adhesive layer 220 may be disposed below the lower surface SC_b of each of the semiconductor dies SC1, SC2, and SC3. The die adhesive layer 220 disposed below the lower surface SC_b of the first semiconductor die SC1 may attach the first semiconductor die SC1 and the package substrate 1000. The die adhesive layer 220 may attach the first semiconductor die SC1 and the second semiconductor die SC2, and the second semiconductor die SC2 and the third semiconductor die SC3.

Referring to FIGS. 3 and 4, a plurality of first signal pads SP1 may be disposed on the upper surface 1000U of the package substrate 1000. The plurality of first signal pads SP1 may be arranged in the first direction D1. The plurality of first signal pads SP1 may be arranged adjacent to the first semiconductor chip 101. The plurality of first signal pads SP1 may be electrically connected to the first semiconductor chip 101 through a plurality of first bonding wires BW1.

A plurality of first ground pads GP1 may be disposed on the upper surface 1000U of the package substrate 1000. The plurality of first ground pads GP1 may be arranged in the first direction D1. The plurality of first ground pads GP1 may be spaced apart from the plurality of first signal pads SP1 in the second direction D2. The plurality of first ground pads GP1 may be spaced apart from the plurality of first signal pads SP1 in the second direction D2 by a first pitch P1. The plurality of first ground pads GP1 may be electrically connected to the first semiconductor chip 101 through a plurality of second bonding wires BW2.

A plurality of second signal pads SP2 may be disposed on the upper surface 1000U of the package substrate 1000. The plurality of second signal pads SP2 may be arranged in the first direction D1. The plurality of second signal pads SP2 may be arranged adjacent to the plurality of memory chips MC. The plurality of second signal pads SP2 may be electrically connected to at least one of the plurality of memory chips MC (e.g., the first semiconductor die SC1) through a plurality of third bonding wires BW3.

The plurality of first signal pads SP1, the plurality of first ground pads GP1, and the plurality of second signal pads SP2 may be disposed on one side of the first semiconductor chip 101. The one side of the first semiconductor chip 101 may be a side facing the plurality of memory chips MC. The plurality of first signal pads SP1, the plurality of first ground pads GP1, and the plurality of second signal pads SP2 may be disposed between the first semiconductor chip 101 and the plurality of memory chips MC. When viewed in a plan view, the first semiconductor chip 101 may be spaced apart from the plurality of first signal pads SP1, the plurality of second signal pads SP2, and the plurality of first ground pads GP1.

The plurality of first signal pads SP1 may be disposed between the plurality of first ground pads GP1 and the plurality of second signal pads SP2. The plurality of first ground pads GP1 may be disposed between the first semiconductor chip 101 and the plurality of first signal pads SP1. The plurality of second signal pads SP2 may be disposed between the plurality of first signal pads SP1 and the plurality of memory chips MC.

The package substrate 1000 may include a plurality of first signal lines SL1 electrically connecting the plurality of first signal pads SP1 and the plurality of second signal pads SP2. The plurality of first signal lines SL1 may be spaced apart from each other in the first direction D1. Each of the plurality of first signal lines SL1 may extend in the second direction D2 and may be connected to a corresponding first signal pad among the plurality of first signal pads SP1 and a corresponding second signal pad among the plurality of second signal pads SP2. In one or more examples, the first signal lines SL1 may be spaced apart from each in the first direction D1 by an equal amount. In one or more examples, at least two first signal lines SL1 may be spaced apart from each other by an amount that is different than the other signal lines SL1.

Accordingly, the first semiconductor chip 101 and the plurality of memory chips MC may be electrically connected to each other. For example, the plurality of first signal lines SL1 may be signal transmission paths between the first semiconductor chip 101 and the plurality of memory chips MC.

The package substrate 1000 may include a plurality of first ground lines GL1 connected to the plurality of first ground pads GP1. At least one of the plurality of first ground lines GL1 may extend between the plurality of first signal pads SP1 and the plurality of first ground pads GP1 in the first direction D1. At least one of the plurality of first ground lines GL1 may extend between the plurality of first signal lines SL1 in the second direction D2.

In detail, the plurality of first ground lines GL1 may include first ground line patterns GLP1, second ground line patterns GLP2, and third ground line patterns GLP3. Each of the first ground line patterns GLP1 may extend in the second direction D2. The first ground line patterns GLP1 may be spaced apart from each other in the first direction D1 with at least one first signal line among the plurality of first signal lines SL1 interposed therebetween. In one or more examples, the first ground line patterns GLP1 may be spaced apart from each in the first direction D1 by an equal amount. In one or more examples, at least two first signal lines SL1 may be spaced apart from each other by an amount that is different than the other signal lines SL1.

The second ground line pattern GLP2 may extend between the plurality of first signal pads SP1 and the plurality of first ground pads GP1 in the first direction D1. The second ground line pattern GLP2 may be electrically connected to the first ground line patterns GLP1.

Each of the third ground line patterns GLP3 may extend from the second ground line pattern GLP2 in the second direction D2. The third ground line patterns GLP3 may be spaced apart from each other in the first direction D1. Each of the third ground line patterns GLP3 may be electrically connected to a corresponding ground pad among the plurality of first ground pads GP1.

The second ground line pattern GLP2 may have a first width W1 in the second direction D2. The first pitch P1 may be greater than the first width W1. The first pitch P1 may be greater than 1 time of the first width W1 and may be less than or equal to 10 times the first width W1. The first width W1 may be 10 μm to 20 μm. The first pitch P1 may be greater than 10 μm and may be less than or equal to 200 μm.

When the first pitch P1 is smaller than the first width W1, at least one ground line cannot extend between the plurality of first ground pads GP1 and the plurality of first signal pads SP1. That is, the plurality of first signal lines SL1 may not be ground shielded through the plurality of first ground lines GL1.

When the first pitch P1 is greater than 10 times the first width W1, a region where the plurality of signal lines SL and the plurality of ground lines GL are arranged may be excessively widened, thereby reducing integration.

In the semiconductor package according to the embodiment of the present disclosure, at least one of the plurality of first ground lines GL1 (e.g., the second ground line pattern GLP2) may extend between the plurality of first signal pads SP1 and the plurality of first ground pads GP1. At least one of the plurality of first ground lines GL1 (e.g., the first ground line pattern GLP1) may extend between the plurality of first signal lines SL1. The plurality of first signal lines SL1 may be ground shielded by the plurality of first ground lines GL1. Interference or crosstalk between the plurality of signal lines SL1 may be prevented. Accordingly, a semiconductor package with improved reliability may be provided.

Referring to FIGS. 3 and 5, a plurality of third signal pads SP3 may be disposed on the upper surface 1000U of the package substrate 1000. The plurality of third signal pads SP3 may be arranged in the first direction D1. The plurality of third signal pads SP3 may be electrically connected to the first semiconductor chip 101 through a plurality of fourth bonding wires BW4.

A plurality of second ground pads GP2 may be disposed on the upper surface 1000U of the package substrate 1000. The plurality of second ground pads GP2 may be arranged in the first direction D1. The plurality of second ground pads GP2 may be spaced apart from the plurality of third signal pads SP3 in the second direction D2. The plurality of second ground pads GP2 may be spaced apart from the plurality of third signal pads SP3 by a second pitch P2 in the second direction D2. The plurality of second ground pads GP2 may be electrically connected to the first semiconductor chip 101 through a plurality of fifth bonding wires BW5.

The plurality of third signal pads SP3 and the plurality of second ground pads GP2 may be disposed on the other side of the first semiconductor chip 101. The other side of the first semiconductor chip 101 may be a side facing the one side of the first semiconductor chip 101. The plurality of second ground pads GP2 may be disposed between the first semiconductor chip 101 and the third signal pads SP3.

The package substrate 1000 may include a plurality of second signal lines SL2 electrically connected to the plurality of third signal pads SP3. The plurality of second signal lines SL2 may extend in the second direction D2. The plurality of second signal lines SL2 may be spaced apart from each other in the first direction D1. In one or more examples, the second signal lines SL2 may be spaced apart from each other in the first direction D1 by an equal amount. In one or more examples, at least two first signal lines SL2 may be spaced apart from each other by an amount that is different than the other signal lines SL2.

The package substrate 1000 may include a plurality of second ground lines GL2 electrically connected to the plurality of second ground pads GP2. At least one of the plurality of second ground lines GL2 may extend between the plurality of third signal pads SP3 and the plurality of second ground pads GP2 in the first direction D1. At least one of the plurality of second ground lines GL2 may extend between the plurality of second signal lines SL2 in the second direction D2.

In detail, the plurality of second ground lines GL2 may include fourth ground line patterns GLP4, fifth ground line patterns GLP5, and sixth ground line patterns GLP6.

Each of the fourth ground line patterns GLP4 may extend in the second direction D2. The fourth ground line patterns GLP4 may be spaced apart from each other in the first direction D1 with at least one second signal line among the plurality of second signal lines SL2 interposed therebetween. In one or more examples, the fourth ground line patterns GLP4 may be spaced apart from each other in the first direction D1 by an equal amount. In one or more examples, at least two fourth ground line patterns GLP4 may be spaced apart from each other by an amount that is different than the other fourth ground line patterns GLP4.

The fifth ground line pattern GLP5 may extend between the plurality of third signal pads SP3 and the plurality of second ground pads GP2 in the first direction D1. The fifth ground line pattern GLP5 may be electrically connected to the fourth ground line patterns GLP4.

Each of the sixth ground line patterns GLP6 may extend from the fifth ground line pattern GLP5 in the second direction D2. The fifth ground line patterns GLP5 may be spaced apart from each other in the first direction D1. The sixth ground line patterns GLP6 may be electrically connected to a corresponding second ground pad among the plurality of second ground pads GP2.

The fifth ground line pattern GLP5 may have a second width W2 in the second direction D2. The second pitch P2 may be greater than the second width W2. The second pitch P2 may be greater than 1 time of the second width W2 and may be may be less than or equal to 10 times the second width W2. The second width W2 may be 10 μm to 20 μm. The second pitch P2 may be greater than 10 μm and may be less than or equal to 200 μm.

When the second pitch P2 is smaller than the second width W2, at least one ground line cannot extend between the plurality of second ground pads GP2 and the plurality of third signal pads SP3. That is, the plurality of second signal lines SL2 may not be ground shielded through the plurality of second ground lines GL2.

When the second pitch P2 is greater than 10 times the second width W2, a region where the plurality of second signal lines SL2 and the plurality of second ground lines GL2 are arranged may be excessively widened, thereby reducing integration.

In a semiconductor package according to one or more embodiments of the present disclosure, at least one of the plurality of second ground lines GL2 (e.g., the fifth ground line pattern GLP5) may extend between the plurality of third signal pads SP3 and the plurality of second ground pads GP2. At least one of the plurality of second ground lines GL2 (e.g., the fourth ground line pattern GLP4) may extend between the plurality of second signal lines SL2. Accordingly, the plurality of second signal lines SL2 may be ground shielded by the plurality of second ground lines GL2. Interference or crosstalk between the plurality of second signal lines SL2 may be prevented. Accordingly, a semiconductor package with improved reliability may be provided.

Referring again to FIG. 3, external connection pads 1400 may be disposed on the lower surface 1000L of the package substrate 1000. The lower insulating layer 1200 may expose the lower surfaces of the external connection pads 1400.

External connection terminals 1500 may be disposed on the lower surface 1000L of the package substrate 1000. The external connection terminals 1500 may be electrically connected to the external connection pads 1400. The external connection terminals may be electrically connected to the plurality of third signal pads SP3 and the plurality of first and second ground pads GP2 through internal wiring lines in the package substrate 1000.

A molding layer 400 may be disposed on the upper surface 1000U of the package substrate 1000. The molding layer 400 may cover the first semiconductor chip 101 and the plurality of memory chips.

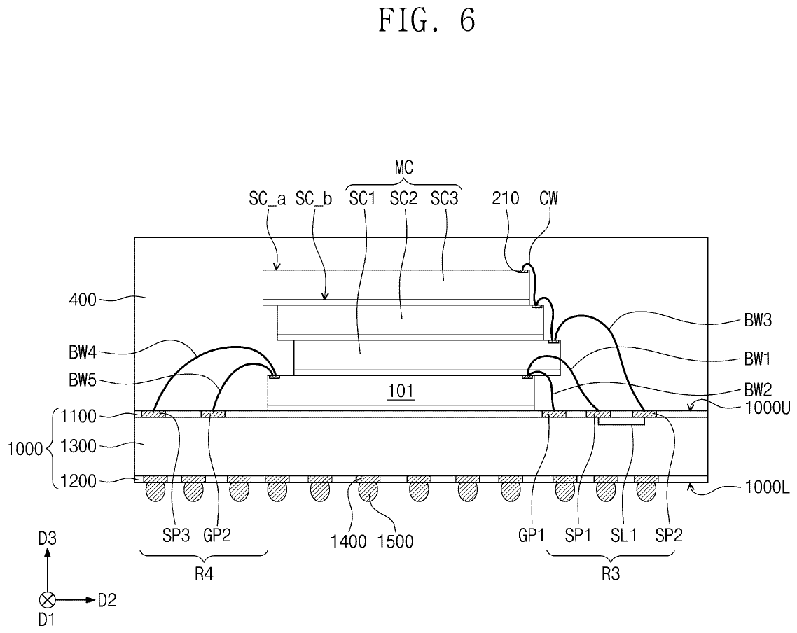

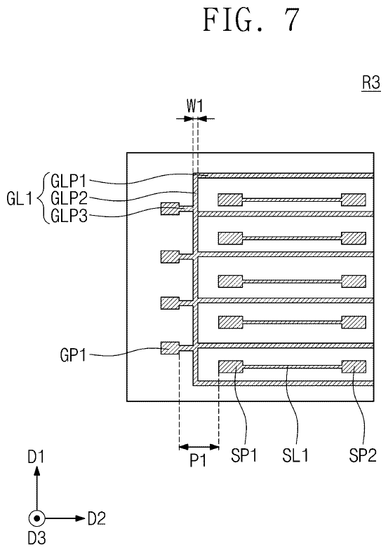

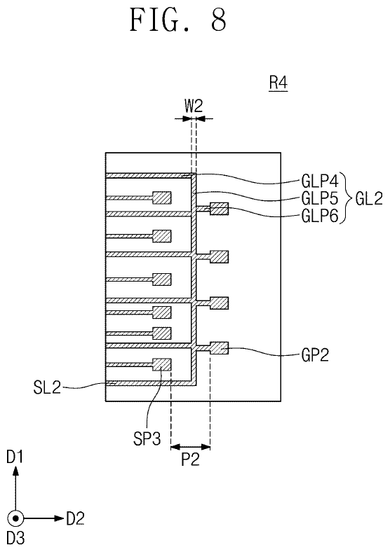

FIG. 6 is a cross-sectional view of a semiconductor package according to other embodiments of the present disclosure. FIG. 7 is a plan view of region ‘R3’ of FIG. 6. FIG. 8 is a plan view of region ‘R4’ region of FIG. 6. For simplicity of explanation, descriptions overlapping those of the semiconductor package described with reference to FIGS. 1 and 2 are omitted.

Referring to FIG. 6, a package substrate 1000 including an upper surface 1000U and a lower surface 1000L facing each other may be provided.

A first semiconductor chip 101 may be provided on the upper surface 1000U of the package substrate 1000. The first semiconductor chip 101 may be, for example, a logic chip. The first semiconductor chip 101 may include, for example, a logic semiconductor chip 100 such as a central processor unit (CPU), a micro processor unit (MPU), a graphics processor unit (GPU), or an application processor (AP).

A plurality of memory chips MC may be disposed on the first semiconductor chip 101. The plurality of memory chips MC may include a first semiconductor die SC1, a second semiconductor die SC2, and a third semiconductor die SC3. The first semiconductor die SC1 may be a semiconductor die adjacent to the package substrate 1000. The second semiconductor die SC2 may be a semiconductor die interposed between the first semiconductor die SC1 and the third semiconductor die SC3.

Each of the plurality of memory chips MC may be, for example, a volatile memory semiconductor chip 100 such as a dynamic random access memory (DRAM) or a static random access memory (SRAM). Each of the plurality of memory chips MC may be a nonvolatile memory semiconductor chip, such as, for example, a flash memory, a phase-change random access memory (PRAM), a magnetic random access memory (MRAM), a ferroelectric random access memory (FeRAM), or a resistive random access memory (RRAM).

Each of the semiconductor dies SC1, SC2, and SC3 may include an upper surface SC_a and a lower surface SC_b facing each other. The lower surface SC_b may be a surface facing the package substrate 1000. The upper surface SC_a of each of the semiconductor dies SC1, SC2, and SC3 may be an active surface. Each of the semiconductor dies SC1, SC2, and SC3 may have a contact pad 210 disposed on the upper surface SC_a.

The contact pad 210 may include a connection terminal that is electrically connected to each of the semiconductor dies SC1, SC2, and SC3. The semiconductor dies SC1, SC2, and SC3 may be electrically connected to each other through a connection wire CW. The connection wire CW may be electrically connected to the contact pads 210 to electrically connect the semiconductor dies to each other. The semiconductor dies SC1, SC2, and SC3 may be spaced apart in the second direction D2 to form a stepped structure.

Referring to FIGS. 6 and 7, a plurality of first signal pads SP1 may be disposed on the upper surface 1000U of the package substrate 1000. The plurality of first signal pads SP1 may be arranged in the first direction D1. The plurality of first signal pads SP1 may be electrically connected to the first semiconductor chip 101 through a plurality of first bonding wires BW1.

A plurality of first ground pads GP1 may be disposed on the upper surface 1000U of the package substrate 1000. The plurality of first ground pads GP1 may be arranged in the first direction D1. The plurality of first ground pads GP1 may be spaced apart from the plurality of first signal pads SP1 in the second direction D2. The plurality of first ground pads GP1 may be spaced apart from the plurality of first signal pads SP1 by a first pitch P1 in the second direction D2. The plurality of first ground pads GP1 may be electrically connected to the first semiconductor chip 101 through a plurality of second bonding wires BW2.

A plurality of second signal pads SP2 may be disposed on the upper surface 1000U of the package substrate 1000. The plurality of second signal pads SP2 may be arranged in the first direction D1. The plurality of second signal pads SP2 may be electrically connected to at least one of the plurality of memory chips MC through a plurality of third bonding wires BW3.

The plurality of first signal pads SP1, the plurality of first ground pads GP1, and the plurality of second signal pads SP2 may be disposed on one side of the first semiconductor chip 101. When viewed in a plan view, the first semiconductor chip 101 may be spaced apart from the plurality of first signal pads SP1, the plurality of second signal pads SP2, and the plurality of first ground pads GP1.

The plurality of first signal pads SP1 may be disposed between the plurality of first ground pads GP1 and the plurality of second signal pads SP2. The plurality of first ground pads GP1 may be disposed between the first semiconductor chip 101 and the plurality of first signal pads SP1.

The package substrate 1000 may include a plurality of first signal lines SL1 that electrically connect the plurality of first signal pads SP1 and the plurality of second signal pads SP2. The plurality of first signal lines SL1 may extend in the second direction D2. The plurality of first signal lines SL1 may be spaced apart from each other in the first direction D1 and may be electrically connected to corresponding first and second signal pads among the plurality of first and second signal pads SP1 and SP2.

Accordingly, the first semiconductor chip 101 and the plurality of memory chips MC may be electrically connected to each other. For example, the plurality of first signal lines SL1 may be signal transmission paths between the first semiconductor chip 101 and the plurality of memory chips MC.

The package substrate 1000 may include a plurality of first ground lines GL1 connected to the plurality of first ground pads GP1. At least one of the plurality of first ground lines GL1 may extend between the plurality of first signal pads SP1 and the plurality of first ground pads GP1 in the first direction D1. At least one of the plurality of first ground lines GL1 may extend between the plurality of first signal lines SL1 in the second direction D2.

In detail, the plurality of first ground lines GL1 may include first ground line patterns GLP1, a second ground line pattern GLP2, and third ground line patterns GLP3.

Each of the first ground line patterns GLP1 may extend in the second direction D2. The first ground line patterns GLP1 may be spaced apart from each other in the first direction D1 with at least one first signal line among the plurality of first signal lines SL1 interposed therebetween.

The second ground line pattern GLP2 may extend between the plurality of first signal pads SP1 and the plurality of first ground pads GP1 in the first direction D1. The second ground line pattern GLP2 may be electrically connected to the first ground line patterns GLP1.

The third ground line patterns GLP3 may extend from the second ground line pattern GLP2 in the second direction D2 and may be spaced apart from each other in the first direction D1. Each of the third ground line patterns GLP3 may be electrically connected to a corresponding ground pad among the plurality of first ground pads GP1.

The second ground line pattern GLP2 may have a first width W1 in the second direction D2. The first pitch P1 may be greater than the first width W1. The first pitch P1 may be greater than 1 time of the first width W1 and may be less than or equal to 10 times the first width W1. The first width W1 may be 10 μm to 20 μm. The first pitch P1 may be greater than 10 μm and may be less than or equal to 200 μm.

When the first pitch P1 is smaller than the first width W1, at least one ground line cannot extend between the plurality of ground pads GP and the plurality of signal pads SP. That is, the plurality of signal lines SL may not be ground shielded through the plurality of ground lines GL.

When the first pitch P1 is greater than 10 times the first width W1, a region where the plurality of signal lines SL and the plurality of ground lines GL are arranged may be excessively widened, thereby reducing integration.

In the semiconductor package according to the embodiment of the present disclosure, at least one of the plurality of first ground lines GL1 (e.g., the second ground line pattern GLP2) may extend between the plurality of first signal pads SP1 and the plurality of first ground pads GP1. At least one of the plurality of first ground lines GL1 (e.g., the first ground line pattern GLP1) may extend between the plurality of first signal lines SL1. The plurality of first signal lines SL1 may be ground shielded by the plurality of first ground lines GL1. Interference or crosstalk between the plurality of signal lines SL1 may be prevented. Accordingly, a semiconductor package with improved reliability may be provided.

Referring to FIGS. 6 and 8, a plurality of third signal pads SP3 may be disposed on the upper surface 1000U of the package substrate 1000. The plurality of third signal pads SP3 may be arranged in the first direction D1. The plurality of third signal pads SP3 may be electrically connected to the first semiconductor chip 101 through a plurality of fourth bonding wires BW4.

A plurality of second ground pads GP2 may be disposed on the upper surface 1000U of the package substrate 1000. The plurality of second ground pads GP2 may be arranged in the first direction D1. The plurality of second ground pads GP2 may be spaced apart from the plurality of third signal pads SP3 in the second direction D2. The plurality of second ground pads GP2 may be spaced apart from the plurality of third signal pads SP3 by a second pitch P2 in the second direction D2. The plurality of second ground pads GP2 may be electrically connected to the first semiconductor chip 101 through a plurality of fifth bonding wires BW5.

Referring to FIG. 6, the first semiconductor chip 101 may be spaced apart from the plurality of third signal pads SP3 and the plurality of second ground pads GP2. The plurality of third signal pads SP3 and the plurality of second ground pads GP2 may be disposed on the other side of the first semiconductor chip 101. The plurality of second ground pads GP2 may be disposed between the plurality of third signal pads SP3 and the first semiconductor chip 101.

The package substrate 1000 may include a plurality of second signal lines SL2 electrically connected to the plurality of third signal pads SP3. The plurality of second signal lines SL2 may extend in the second direction D2. The plurality of second signal lines SL2 may be spaced apart from each other in the first direction D1.

The package substrate 1000 may include a plurality of second ground lines GL2 electrically connected to the plurality of second ground pads GP2. At least one of the plurality of second ground lines GL2 may extend between the plurality of third signal pads SP3 and the plurality of second ground pads GP2 in the second direction D2. At least one of the plurality of second ground lines GL2 may extend between the plurality of second signal lines SL2 in the first direction D1.

In detail, the plurality of second ground lines GL2 may include fourth ground line patterns GLP4, fifth ground line patterns GLP5, and sixth ground line patterns GLP6.

Each of the fourth ground line patterns GLP4 may extend in the second direction D2. The fourth ground line patterns GLP4 may be spaced apart from each other in the first direction D1 with at least one second signal line among the plurality of second signal lines SL2 interposed therebetween.

The fifth ground line pattern GLP5 may extend between the plurality of third signal pads SP3 and the plurality of second ground pads GP2 in the first direction D1. The fifth ground line pattern GLP5 may be electrically connected to the fourth ground line patterns GLP4.

Each of the sixth ground line patterns GLP6 may extend from the fifth ground line pattern GLP5 in the second direction D2 and may be spaced apart from each other in the first direction D1. The sixth ground line patterns GLP6 may be electrically connected to a corresponding second ground pad among the plurality of second ground pads GP2.

Each of the fifth ground line patterns GLP5 may have a second width W2 in the second direction D2. The second pitch P2 may be greater than the second width W2. The second pitch P2 may be greater than 1 time of the second width W2 and may be less than or equal to 10 times the second width W2. The second width W2 may be 10 μm to 20 μm. The second pitch P2 may be greater than 10 μm and may be less than or equal to 200 μm.

When the second pitch P2 is smaller than the second width W2, at least one ground line cannot extend between the plurality of second ground pads GP2 and the plurality of third signal pads SP3. In other words, the plurality of second signal lines SL2 may not be ground shielded through the plurality of second ground lines GL2.

When the second pitch P2 is greater than 10 times the second width W2, a region where the plurality of second signal lines SL2 and the plurality of second ground lines GL2 are arranged may be excessively widened, thereby reducing integration.

In the semiconductor package according to the embodiment of the present disclosure, at least one of the plurality of second ground lines GL2 (e.g., the fifth ground line pattern GLP5) may extend between the plurality of third signal pads SP3 and the plurality of second ground pads GP2. At least one of the plurality of second ground lines GL2 (e.g., the fourth ground line pattern GLP4) may be extended between the plurality of second signal lines SL2. As a result, the plurality of second signal lines SL2 may be ground shielded by the plurality of second ground lines GL2. Interference or crosstalk between the plurality of second signal lines SL2 may be prevented. Accordingly, a semiconductor package with improved reliability may be provided.

Referring again to FIG. 6, external connection pads 1400 may be disposed on the lower surface 1000L of the package substrate 1000. The lower insulating layer 1200 may expose the lower surfaces of the external connection pads 1400.

External connection terminals 1500 may be disposed on the lower surface 1000L of the package substrate 1000. The external connection terminals 1500 may be electrically connected to the external connection pads 1400. The external connection terminals may be electrically connected to the plurality of third signal pads SP3 and the plurality of first and second ground pads GP2 through internal wiring lines in the package substrate 1000.

A molding layer 400 may be disposed on the upper surface 1000U of the package substrate 1000. The molding layer 400 may cover the first semiconductor chip 101 and the plurality of memory chips.

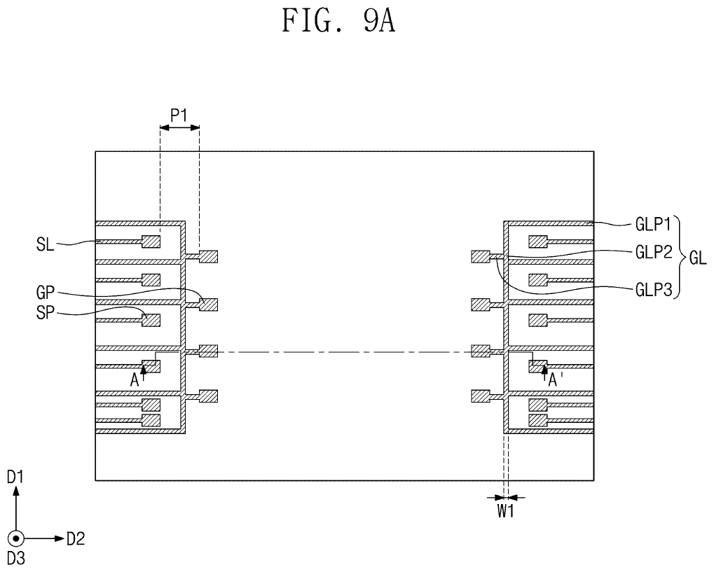

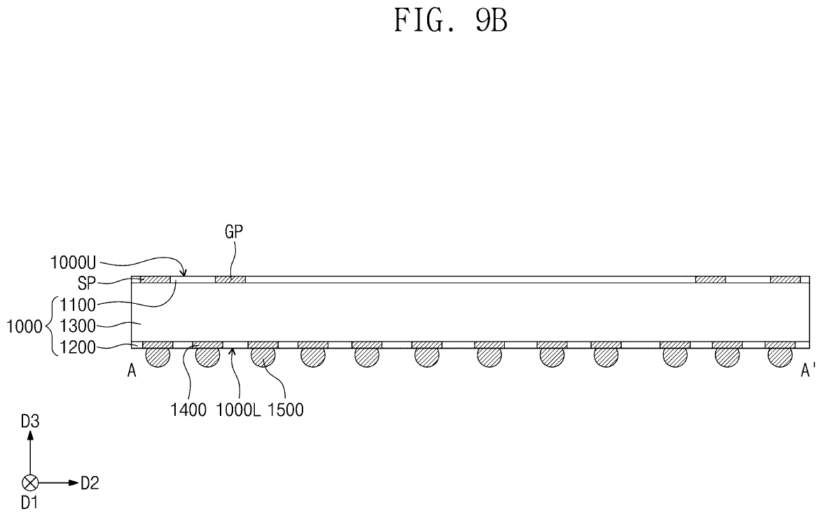

FIGS. 9A to 11A are plan views illustrating a method for manufacturing a semiconductor package according to embodiments of the present disclosure. FIGS. 9B to 11B are cross-sectional views along A-A′ of FIGS. 9A to 11A. For simplicity of explanation, any description overlapping the semiconductor package described with reference to FIGS. 1 and 2 will be omitted.

Referring to FIGS. 9A and 9B, a package substrate 1000 including an upper surface 1000U and a lower surface 1000L facing each other may be provided. The package substrate 1000 may include a base layer 1300, an upper insulating layer 1100 on the base layer 1300, and a lower insulating layer 1200 below the base layer 1300. A plurality of ground pads GP and a plurality of signal pads SP may be formed on the upper surface 1000U of the package substrate 1000.

The plurality of signal pads SP may be disposed on the upper surface 1000U of the package substrate 1000. The plurality of signal pads SP may be arranged in the first direction D1.

The plurality of ground pads GP may be disposed on the upper surface 1000U of the package substrate 1000. The plurality of ground pads GP may be arranged in the first direction D1. The plurality of ground pads GP may be spaced apart from the plurality of signal pads SP in the second direction D2. The plurality of ground pads GP may be spaced apart from the plurality of signal pads SP by a first pitch P1 in the second direction D2.

Forming the plurality of ground pads and the plurality of signal pads may include, for example, plating and patterning a metal material on the base layer 1300 to form the plurality of ground pads and the plurality of signal pads, depositing the upper insulating layer 1100 on the plurality of ground pads and the plurality of signal pads, and patterning the upper insulating layer 1100 to expose upper surfaces of the plurality of ground pads and the plurality of signal pads.

A plurality of signal lines SL electrically connected to the plurality of signal pads SP may be formed on the package substrate 1000. The plurality of signal lines SL may be spaced apart from each other in the first direction D1. Each of the plurality of signal lines SL may extend in the second direction D2 and may be electrically connected to a corresponding signal pad among the plurality of signal pads SP.

A plurality of ground lines GL electrically connected to the plurality of ground pads GP may be formed on the package substrate 1000. Forming the plurality of signal lines and the plurality of ground lines may include, for example, plating and patterning a metal material on the base layer 1300 to form the plurality of signal lines and the plurality of ground lines, and depositing the upper insulating layer 1100.

At least one of the plurality of ground lines GL may extend between the plurality of signal pads SP and the plurality of ground pads GP. At least one of the plurality of ground lines GL may extend between the plurality of signal lines SL. The plurality of ground lines GL may include first ground line patterns GLP1, second ground line patterns GLP2, and third ground line patterns GLP3. Each of the first ground line patterns GLP1 may extend in the second direction D2. The first ground line patterns GLP1 may be spaced apart from each other in the first direction D1 with at least one signal line among the plurality of signal lines SL interposed therebetween.

The second ground line pattern GLP2 may extend between the plurality of signal pads SP and the plurality of ground pads GP in the first direction D1. The second ground line pattern GLP2 may be electrically connected to the first ground line patterns GLP1.

The third ground line patterns GLP3 may extend from the second ground line pattern GLP2 in the second direction D2 and may be spaced apart from each other in the first direction D1. Each of the third ground line patterns GLP3 may be electrically connected to a corresponding ground pad among the plurality of ground pads GP.

The second ground line pattern GLP2 may have a first width W1 in the second direction D2. The first pitch P1 may be greater than the first width W1. The first pitch P1 may be greater than 1 time of the first width W1 and may be less than or equal to 10 times the first width W1. The first width W1 may be 10 μm to 20 μm. The first pitch P1 may be greater than 10 μm and may be less than or equal to 200 μm.

When the first pitch P1 is smaller than the first width W1, at least one ground line cannot extend between the plurality of ground pads GP and the plurality of signal pads SP. That is, the plurality of signal lines SL may not be ground shielded through the plurality of ground lines GL.

When the first pitch P1 is greater than 10 times the first width W1, a region where the plurality of signal lines SL and the plurality of ground lines GL are arranged may be excessively widened, thereby reducing integration.

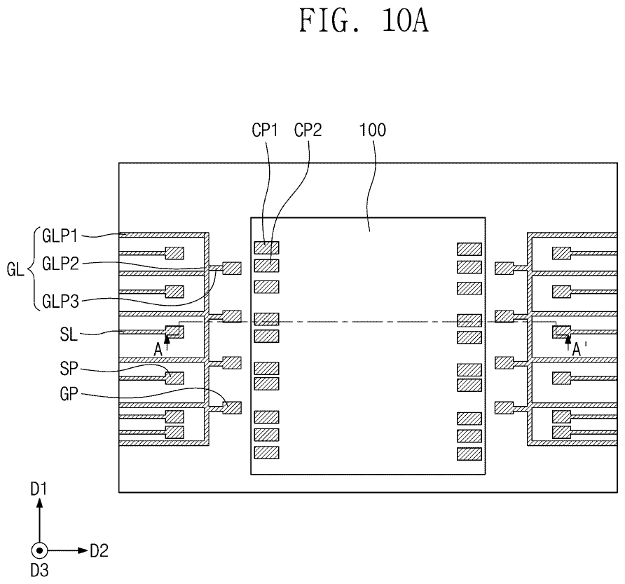

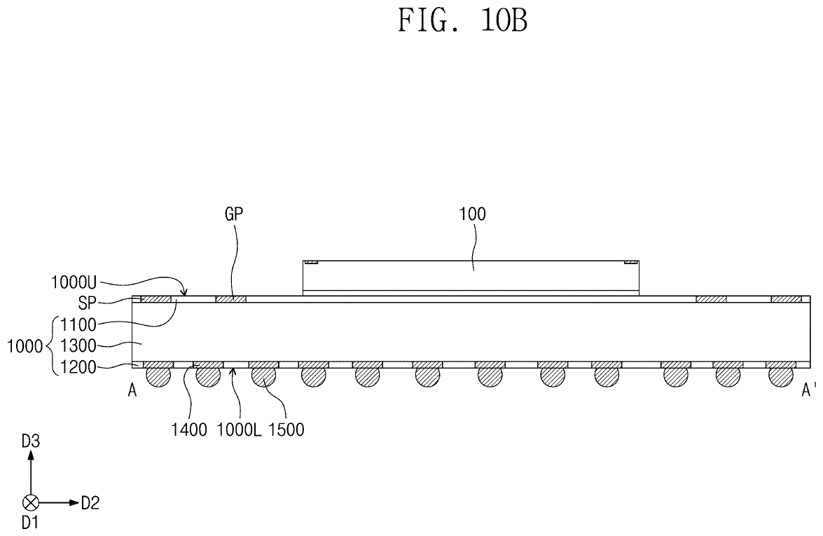

Referring to FIGS. 10A and 10B, a semiconductor chip 100 may be disposed on the upper surface 1000U of the package substrate 1000. The semiconductor chip 100 may be attached to the upper surface 1000U of the package substrate 1000 through, for example, an adhesive layer or a bonding tape.

The semiconductor chip 100 may include a plurality of first pads CP1 and a plurality of second pads CP2. The semiconductor chip 100 may be disposed to be spaced apart from the plurality of ground pads GP and the plurality of signal pads SP when viewed in a plan view. The semiconductor chip 100 may be disposed to be spaced apart from the plurality of ground lines GL and the plurality of signal lines SL when viewed in a plan view.

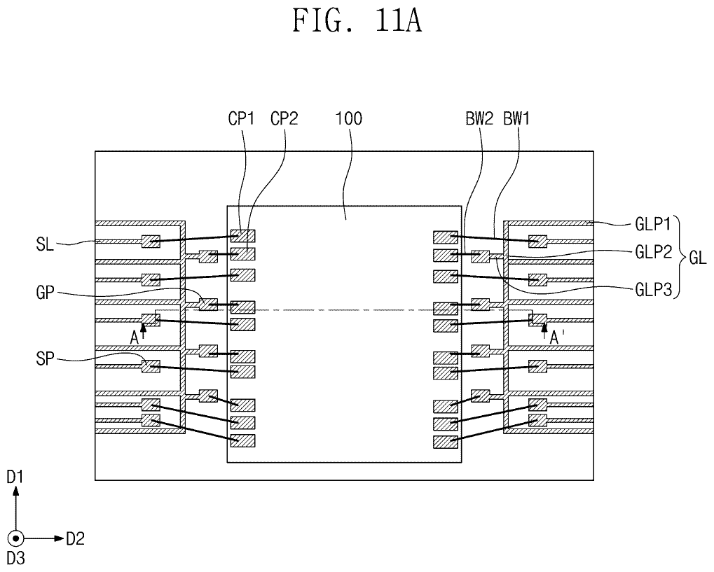

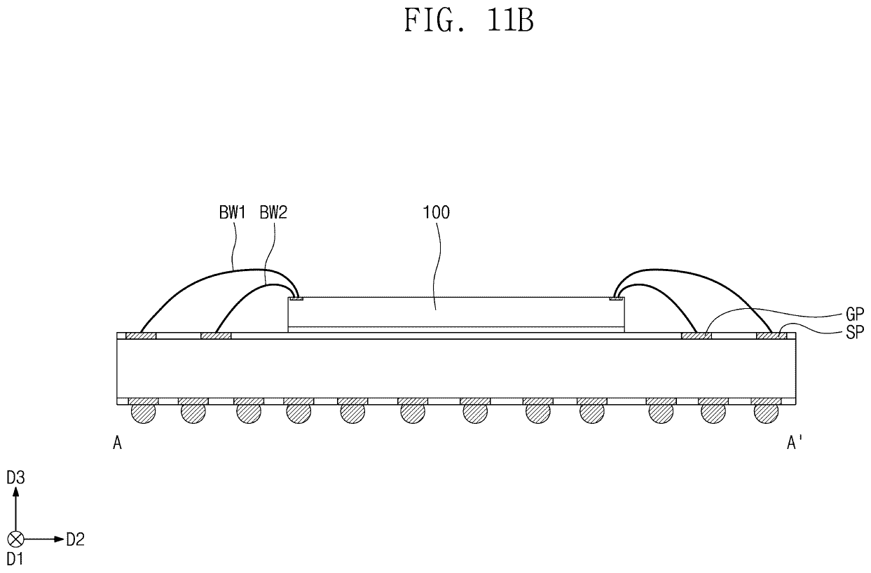

Referring to FIGS. 11A and 11B, a wire bonding process may be performed to connect the semiconductor chip 100 and the plurality of signal pads SP with a plurality of first bonding wires BW1. The wire bonding process may utilize, for example, a capillary. One end of each of the plurality of first bonding wires BW1 may be connected to a corresponding signal pad among the plurality of signal pads SP. The other end of each of the plurality of first bonding wires BW1 may be connected to a corresponding first pad among the plurality of first pads CP1 of the semiconductor chip 100.

A wire bonding process may be performed to connect the semiconductor chip 100 and the plurality of ground pads GP with a plurality of second bonding wires BW2. The wire bonding process may utilize, for example, a capillary. One end of each of the plurality of second bonding wires BW2 may be connected to corresponding ground pads among the plurality of ground pads GP. The other end of each of the plurality of second bonding wires BW1 may be connected to corresponding second pads among the plurality of second pads CP2 of the semiconductor chip 100.

Referring again to FIGS. 1 and 2, a molding layer 400 may be formed on the upper surface 1000U of the package substrate 1000. The molding layer 400 may cover the semiconductor chip 100 and the plurality of first and second bonding wires BW1 and BW2.

According to one or more embodiments of the present disclosure, the semiconductor package may include at least one of the plurality of ground lines extending between the plurality of signal pads and ground pads. At least one of the plurality of ground lines may extend between the plurality of signal lines. As a result, the plurality of signal lines may be ground shielded by the plurality of ground lines. The interference or crosstalk between the plurality of signal lines may be prevented. Accordingly, the semiconductor package with improved reliability may be provided.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A semiconductor package comprising:
a package substrate comprising a first surface and a second surface opposite to each other;
at least one signal pad on the first surface of the package substrate, the first direction being a direction parallel to the first surface of the package substrate;
at least one ground pad on the first surface of the package substrate and spaced apart from the signal pad in a second direction, the second direction being a direction parallel to the first surface of the package substrate and intersecting the first direction; and
a semiconductor chip on the package substrate, the semiconductor chip comprising at least one first pad and at least one second pad,
wherein the package substrate further comprises:
at least one signal line connected to the at least one signal pad; and
at least one ground line connected to the at least one ground pad,
wherein the at least one ground line extends between the at least one signal pad and the at least one ground pad in the first direction,
wherein the at least one first pad is connected to the at least one signal pad through a first bonding wire, and
wherein the at least one second pad is connected to the at least one ground pad through a second bonding wire.

2. The semiconductor package of claim 1, wherein the at least one ground line extends between the at least one signal lines.

3. The semiconductor package of claim 1, wherein a signal pad among the at least one signal pad and a ground pad, adjacent to the signal pad, among the at least one ground pad are spaced apart from each other by a first distance in the second direction.

4. The semiconductor package of claim 3, wherein at the least one ground line has a first width in the second direction, and
wherein the first distance is greater than the first width.

5. The semiconductor package of claim 4, wherein the first distance is greater than the first width and is smaller than or equal to 10 times the first width.

6. The semiconductor package of claim 4, wherein the first width is 10 μm to 20 μm, and
wherein the first distance is greater than 10 μm and is less than or equal to 200 μm.

7. The semiconductor package of claim 1, wherein the semiconductor chip is spaced apart from the at least one signal pad and the at least one ground pad in the second direction.

8. The semiconductor package of claim 1, wherein the semiconductor chip is spaced apart from the at least one signal line and the at least one ground line in the second direction.

9. The semiconductor package of claim 1, wherein the at least one ground line comprises a plurality of ground lines which comprise:
at least one first ground line pattern extending in the second direction and spaced apart from each other in the first direction with the at least one signal line interposed therebetween;
a second ground line pattern extending between the at least one signal pad and the at least one ground pad in the first direction and connected to the at least one first ground line pattern; and
a third ground line pattern extending from the second ground line pattern in the second direction and connected to a corresponding ground pad among the at least one ground pad.

10. The semiconductor package of claim 1, wherein each of the first bonding wire and the second bonding wire comprises at least one of copper, gold, aluminum, and an alloy thereof.

11. A semiconductor package comprising:
a package substrate comprising a first surface and a second surface opposite to each other;
a first semiconductor chip on the first surface of the package substrate;
a plurality of memory chips on the first surface of the package substrate;
a plurality of first signal pads on the first surface of the package substrate and arranged in a first direction, the first direction being a direction parallel to the first surface of the package substrate;
a plurality of ground pads on the first surface of the package substrate and arranged in the first direction and spaced apart from the plurality of first signal pads in a second direction, respectively, the second direction being a direction parallel to the first surface of the package substrate and intersecting the first direction;
a plurality of second signal pads on the first surface of the package substrate and arranged in the first direction;
a plurality of first bonding wires connecting the plurality of first signal pads and the first semiconductor chip, respectively;
a plurality of second bonding wires connecting the plurality of ground pads and the first semiconductor chip, respectively; and
a plurality of third bonding wires connecting the plurality of second signal pads and the plurality of memory chips, respectively,
wherein the plurality of first signal pads are disposed between the plurality of ground pads and the plurality of second signal pads, respectively,
wherein the package substrate comprises:
a plurality of signal lines connecting the plurality of first signal pads and the plurality of second signal pads, respectively; and
a plurality of ground lines connected to the plurality of ground pads, respectively, and
wherein at least one of the plurality of ground lines extends between the plurality of ground pads and the plurality of first signal pads in the first direction, respectively.

12. The semiconductor package of claim 11, wherein the plurality of first signal pads and the plurality of ground pads are spaced apart from each other by a first distance in the second direction.

13. The semiconductor package of claim 12, wherein each of the plurality of ground lines has a first width in the second direction, and
wherein the first distance is greater than the first width and less than or equal to 10 times the first width.

14. The semiconductor package of claim 11, wherein the first semiconductor chip is spaced apart from the plurality of first signal pads, the plurality of second signal pads, and the plurality of ground pads in the second direction.

15. The semiconductor package of claim 11, wherein the plurality of ground lines comprise:
a plurality of first ground line patterns extending in the second direction and spaced apart from each other in the first direction with at least one signal line of the plurality of signal lines interposed therebetween;
a second ground line pattern extending between the plurality of first signal pads and the plurality of ground pads in the first direction and connected to the plurality of first ground line patterns; and
a third ground line pattern extending from the second ground line pattern in the second direction and connected to a corresponding ground pad of the plurality of ground pads.

16. The semiconductor package of claim 11, wherein the first semiconductor chip comprises a logic chip.

17. A semiconductor package comprising:
a package substrate comprising a first surface and a second surface opposite to each other;
a first semiconductor chip on the first surface of the package substrate;
a plurality of memory chips on the first surface of the package substrate and stacked on the first semiconductor chip;
a plurality of first signal pads arranged in a first direction on the first surface of the package substrate, the first direction being a direction parallel to the first surface of the package substrate;
a plurality of ground pads arranged in the first direction on the first surface of the package substrate and spaced apart from the plurality of first signal pads, respectively, in a second direction, the second direction being a direction parallel to the first surface of the package substrate and intersecting the first direction;
a plurality of second signal pads on the first surface of the package substrate and arranged in the first direction;
a plurality of first bonding wires connecting the plurality of first signal pads and the first semiconductor chip, respectively;
a plurality of second bonding wires connecting the plurality of ground pads and the first semiconductor chip, respectively; and
a plurality of third bonding wires connecting the plurality of second signal pads and the plurality of memory chips, respectively,
wherein the plurality of first signal pads are between the plurality of ground pads and the plurality of second signal pads, respectively,
wherein the package substrate comprises:
a plurality of signal lines connecting the plurality of first signal pads and the plurality of second signal pads, respectively; and
a plurality of ground lines connected to the plurality of ground pads, and
wherein at least one of the plurality of ground lines extends between the plurality of ground pads and the plurality of first signal pads in the first direction, respectively.

18. The semiconductor package of claim 17, wherein the plurality of first signal pads are respectively spaced apart from the plurality of ground pads by a first distance in the second direction.

19. The semiconductor package of claim 17, wherein the plurality of ground lines comprise:
a plurality of first ground line patterns extending in the second direction and spaced apart in the first direction with at least one of the plurality of signal lines interposed therebetween;
a second ground line pattern extending between the plurality of first signal pads and the plurality of ground pads, respectively, in the first direction and connected to the plurality of first ground line patterns, respectively; and
a third ground line pattern extending from the second ground line pattern in the second direction and connected to a corresponding ground pad among the plurality of ground pads.

20. The semiconductor package of claim 17, wherein each of the plurality of first bonding wires and the plurality of second bonding wires comprises at least one of copper, gold, aluminum, and an alloy thereof.
